(19) United States
(12) Patent Application Publication
(10) Pub. No.: US 2025/0361593 A1
(43) Pub. Date: Nov. 27, 2025

(54) PLUMBING FIXTURE FINISH

(71) Applicant: Kohler Co., Kohler, WI (US)

(72) Inventor: Sarfaraz Moh, Kohler, WI (US)

(21) Appl. No.: 19/201,318

(22) Filed: May 7, 2025

Related U.S. Application Data
(60) Provisional application No. 63/650,211, filed on May 21, 2024.
(60) Provisional application No. 63/761,086, filed on Feb. 20, 2025.

(51) Int. Cl. C23C 14/00; C23C 14/16; C23C 14/24

(52) U.S. Cl. CPC C23C 14/0015; C23C 14/16; C23C 14/24

(57) ABSTRACT

A method for application of a finish for a hardware set includes heating a chamber, pressurizing the chamber including the hardware set to create a vacuum in the chamber, applying at least one gas to an ionized target material in the chamber for a non-reactive coating layer, and providing at least one gas to the chamber at a dynamically increasing pressure over a predetermined time range for a coating having a predetermined color. An apparatus includes a rack configured to hold the hardware set in a chamber and to distribute the finish on the hardware set, a vacuum pump to create a vacuum, an electric input to increase a voltage of a target material, a heating element to increase a temperature in the apparatus, and a gas inlet pipe configured to gas for a nonreactive coating to the hardware set and gas for a reactive coating.

### CROSS REFERENCE TO RELATED APPLICATIONS

This application claims priority benefit of Provisional Application No. 63/761,086 (Docket No. 010222-24007B) filed Feb. 20, 2025, and Provisional Application No. 63/650,211 (Docket No. 010222-24007A) filed May 21, 2024, each of which are hereby incorporated by reference in its entirety.

### FIELD

The present disclosure relates generally to one or more finishes or coatings applied to plumbing fixtures.

### BACKGROUND

Plumbing fixtures often have coatings in a variety of colors and styles. Challenges have arisen surrounding the application of dark color coatings to plumbing fixtures.

### BRIEF DESCRIPTION OF THE DRAWINGS

Exemplary embodiments are described herein with reference to the following drawings, according to an exemplary embodiment.

FIG. 1 is an example apparatus for forming coatings on plumbing fixtures.

FIG. 2 is a block diagram for the apparatus of FIG. 1.

FIG. 3 is a flow chart for forming coatings on plumbing fixtures.

FIG. 4 is a flow chart for forming coatings on plumbing fixtures.

FIG. 5 illustrates an example control system.

FIG. 6 illustrates a flow chart for the control system of FIG. 5.

FIG. 7 illustrates a flow chart for formation of a cleanable surface on plumbing fixtures through modification of a coating of FIG. 1-4.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

The present disclosure provides for a method and apparatus for forming a finish to a fixture, and fixtures having such finish. The fixture may be related to plumbing (i.e., plumbing fixture) and include one or more passages, valves or chambers for the passage and/or diversion of water or other liquids. The plumbing fixture is not meant to be limited and may be any household plumbing fixture associated with delivering and draining water. The plumbing fixture may be at least one of faucets for sinks, tubs, whirlpools, shower heads, spas, soap dispensers, and the like; faucet handles; faucet accessories such as fluid conduits (e.g., water piping, hoses, etc.); or water containers or vessels such as sinks, tubs, whirlpools, spas, etc. In another embodiment, the finish may also be applied to other fixtures, such as bathroom or kitchen fixtures such as towel holders, lighting fixtures, or ventilation fixtures. Moreover, the surface finish may be applied to a surface of the fixture that is made from at least one of a low-corrosive metal or metal alloys (e.g., tungsten, titanium, chrome, pewter, copper, bronze, brass, stainless steel, zinc alloys), ceramic (e.g., porcelain), glass, plastic, or combinations thereof.

The following processes may include depositing a coating on the plumbing fixture to obtain a finish having a desired appearance. The step of depositing the first coating may be conducted using at least one of a vacuum deposition (physical vapor deposition, PVD; chemical vapor deposition, CVD; atomic layer deposition, ALD). In one embodiment, PVD is used as the deposition technique for forming the first coating on the plumbing fixture.

PVD vacuum deposition processes are advantageous because the processes involve no aqueous component and are more environmentally friendly and economical than wet chemical processes. PVD coatings are typically harder and more corrosion-resistant than coatings applied by electroplating. Most PVD coatings have high temperature and good impact strength, excellent abrasion resistance, and are durable such that protective topcoats are optional. PVD deposition processes include at least one of cathodic arc evaporation, electron beam (e-beam) PVD, evaporative deposition, pulsed-laser deposition, sputter deposition, ion plating, or pulsed-electron deposition. In typical PVD processes, a material is vaporized from a solid source and transported in a vacuum environment as a vapor to a substrate where it condenses, forming a coating. The vacuum environment is configured such that the mean free path for collision between particles is on the order of the dimensions of the processing chamber or through a low-pressure environment of gas or plasma (ionized gas).

The process for depositing finishes of dark colors, such as black or graphite, vary from other colors. For example, the dark color finish may use a different nonreactive coating compared to other finishes. The PVD finish itself is comprised of chromium metal and various gases to form layers of chromium nitrides and carbonitrides. The coating strength is increased with this technique.

Dark colors, such as graphite or black, may include non-reactive coating being comprised of many layers of chromium metal (Cr) and chromium nitride (CrN) stacked on top of one another. Chromium is a very hard metal that provides scratch and corrosion resistance. CrN is an interstitial compound, which includes a compact lattice structure with nitrogen atoms filling the gaps of the Cr lattice. This is another very hard and extremely corrosion resistant coating layer. Overall, this method of non-reactive coating provides corrosion resistance and strength.

In the main reactive coating layer, the standard steps in PVD processes use full gases from the start the coating but in the graphite finish, the gases are ramped up until the end of the coating time. The advantage of this process is that durability and corrosion resistance of the coating is improved. This also leads to a cleaner chamber. As the coating is black, the coating produces a lot of dust that is not good for the chamber and may be cleaned often. Cleaning requirements are reduced with ramping.

The following processes may also include creation of a cleanable surface using the PVD coating. A cleanable surface may have a property such as hydrophobic to water, oil, and/or other liquids. Example cleanable surfaces include fluoropolymers. One example is fluoropolymer of tetrafluoroethylene PTFE, which may be referred to as Teflon in certain formulations from certain sources.

In some instances, such cleanable surfaces may be deposited on a material by adding a silicon oxide (SiO2) to a substrate. The silicon oxide may be deposited by a sputter PVD process. The silicon oxide acts as an adhesion layer. On top of the adhesion layer, a coating is deposited, for example, using a thermal evaporation PVD process. This procedure is complex. A chamber that can accommodate three different PVD processes is not realistic for production due to complexity and costs. In addition, depositing the silicon oxide layer may cause a color shift on the target (plumbing fixture). The color shift may be more dramatic when the plumbing fixture has a zirconium coating.

One or more of the following embodiments may overcome these downfalls by application of such a cleanable surface through oxidation of the PVD color layer. An ion source for oxygen (O2) has may be applied to the target (plumbing fixture). The organic coating is deposited using the thermal evaporation process. This process eliminates the need for the silicon oxide layer. In addition, the color shift caused from the silicon oxide layer is avoided.

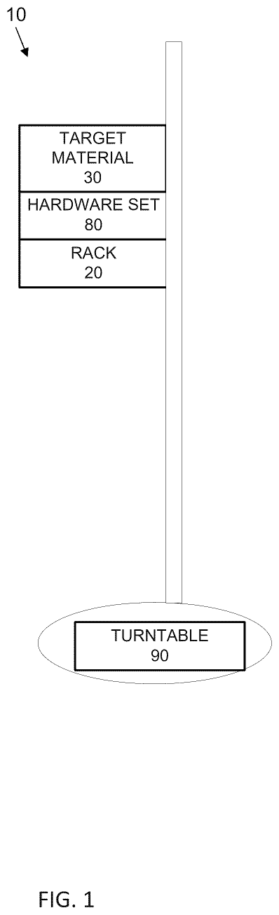

FIG. 1 is an example apparatus for forming coatings on plumbing fixtures or other hardware. An example hardware set 80 as a faucet is illustrated. The hardware set 80 may be supported by a rack 20. The hardware set 80 may include a target material (e.g., the outer layer or other material of the hardware set 80) that is subjected to the following processes. While other examples are possible, the target material 30 may include chrome, zirconium, or titanium.

The apparatus may include a turntable 90 for rotating the hardware set 80.

The turntable 90 may include or otherwise be coupled to a motor that rotates the turntable 90. The motor may rotate the turntable in response to a user input at the apparatus (e.g., a button or lever) or a wireless communication (e.g., from a mobile device or remote controller). The apparatus may include a housing for enclosing the chamber in an airtight manner. Additional, different or fewer components may be included.

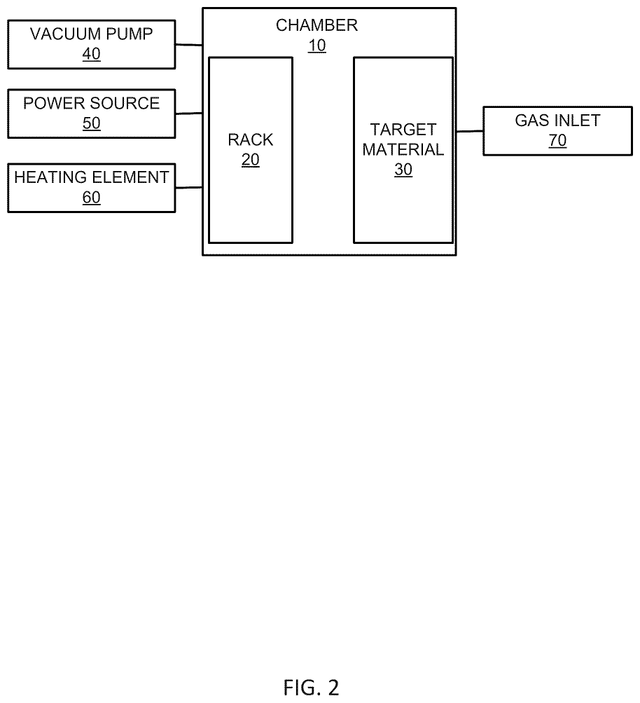

FIG. 2 is a block diagram for the apparatus of FIG. 1. The chamber 10 includes at least the rack 20 configured to support the target material 30. The chamber is connected to multiple inputs including a gas input (e.g., gas inlet 70), an electrical input (e.g., power source 50), a heat input (e.g., heating element 60), and a vacuum input (e.g., vacuum pump 40). As described in more detail below, manual controls or an automated controller or feedback system activate or enable the various inputs at different times according to the PVD process.

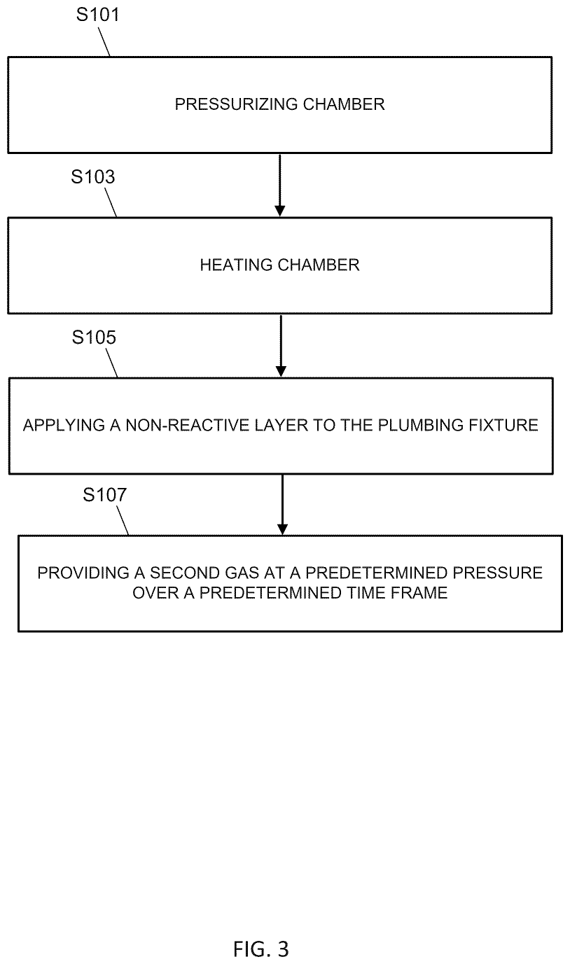

FIG. 3 is a flow chart for forming coatings or a finish on plumbing fixtures. Additional, different or fewer acts may be included.

At act S101, the chamber 10 is depressurized. For example, vacuum pump 40 may pump air out of the chamber 10 in order to create a vacuum (e.g., pressure level below a vacuum threshold).

At act S103, the chamber 10 is heated. The chamber 10 may include the heating element 60 to which electrical power is applied and converted to heat. Acts S101 and S103 may be performed simultaneously or in overlapping time intervals.

At act S105, a first layer (e.g., non-reactive layer) is applied to the plumbing fixture (e.g., target material 30). For example, at least one gas is provided through the gas inlet 70 to an ionized target material in the chamber 10.

At act $107, a second layer (e.g., reactive layer) is applied to the plumbing fixture (e.g., target material 30). For example, at least one gas to the chamber at a dynamically increasing pressure over a predetermined time range for a coating having a predetermined color.

After this process, the plumbing fixture or hardware set includes a base substrate, a chromium layer formed from a first gas reacting with an ionized target material, and a chromium nitrate layer formed from a second gas reacting with the ionized target material.

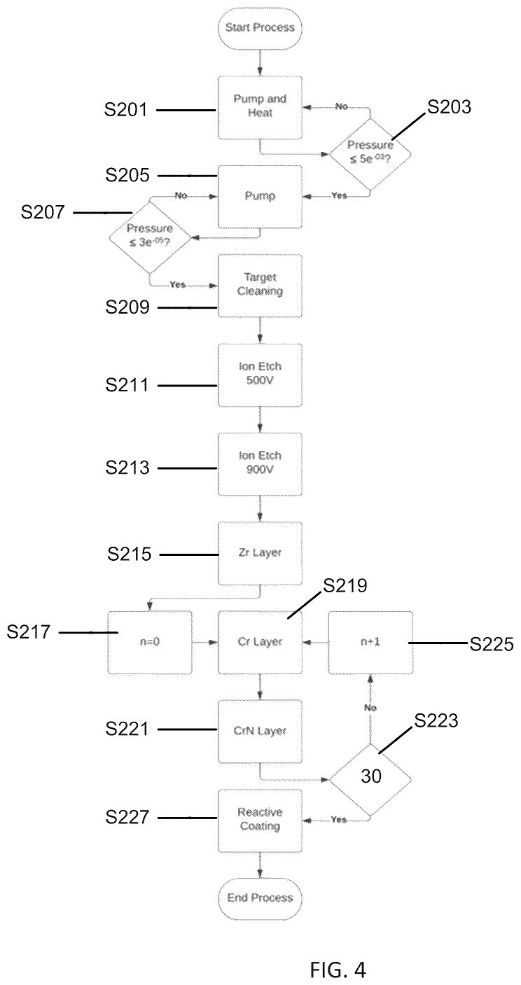

FIG. 4 is a more detailed example flow chart for forming coatings on plumbing fixtures. Additional, different or fewer acts may be included.

At act S201, pump and heat are applied to the chamber 10.

As shown at act S203, the pressure of the chamber 10 is monitored, for example, using a pressure sensor. When the vacuum pressure falls below a predetermined level 0.005 mbar, the heating element 60 is deactivated.

As shown at act S205 the pump continues to reduce the pressure in the chamber 10. Once the pressure falls below a second predetermined level, 0.003 mbar, then the process moves the act S209 where the target is cleaned. Contamination or oxidation may be removed by adding voltage.

At act S211, an ion etch is applied at a first voltage level. One example first voltage level is 500 V. The ion etch may include a plasma or ion beam that is applied to the target material. The first voltage is a low voltage applied to the substrate for cleaning.

At act S213, an ion etch is applied at a second voltage level. One example second voltage level is 900 V. The second voltage is a high voltage applied to the substrate for cleaning. The high voltage is greater than the low voltage.

At act S215, a sublayer is applied. The sublayer may be a zirconium (Zr) layer applied. A first gas reacts with the ionized target material to create the non-reactive coating layer. The first gas may be argon, nitrogen, oxygen, or acetylene.

The control system sets a counter for the Cr layers. At S217, a counter n is set to an initial value (e.g., n=0). At S219, a Cr layer is applied. At S221, a CrN layer is applied. Through this sequence, the non-reactive coating layer is formed with a first layer made of chromium and a second layer made of chromium nitride.

At S223, the counter n is compared to a threshold. Example thresholds for n included 10 to 50. Other values are possible. If the counter has not reached the threshold, the counter is incremented at S225 and acts S219 and S221 are repeated. The threshold is one less than the number of times that the gas is applied to the ionized target material. Thus, when the threshold is n, n+1 layers are applied.

When the counter n reaches the threshold, the reactive coating S227 is applied. During the application, the gas is provided at an increasing pressure level over a predetermined period. The predetermined time range may be any value from 10 to 60 minutes.

In one embodiment, the step of depositing the coating includes depositing the coating on the entire surface area of the plumbing fixture. In another embodiment, only a portion of the surface area of the fixture is coated with the coating. Other portions of the plumbing fixture may be at least one of a polished metal, brushed metal, gold-plated, oil-rubbed metal, satin metals or combinations thereof. Non-limiting examples of the first finish include polished chrome, brushed chrome, polished French gold, polished titanium, brushed titanium, polished rose gold, polished modern gold, polished tungsten, polished modern brass, satin titanium, polished satin chrome, satin bronze, polished brass, satin brass, oil-rubbed bronze, polished nickel, brushed nickel, matte black, and the like.

In some embodiments, the PVD process of the coating is a reactive deposition process whereby the depositing species reacts with a gas species in the processing environment to form a compound prior to depositing (e.g., nitrogen reacting with depositing titanium to form a coating of TiN (having a gold appearance)). Decorative/wear PVD coatings for plumbing fixtures include TiN (having a gold appearance), ZrN (having a brass-like appearance), TiC (having a black appearance), TiCN (having an “anthracite gray” appearance), ZrCN (having a nickel-like appearance), ZrCrCN (having a brass-like appearance), and ZrCrN (having a gold or rose-gold appearance). In one embodiment, a thickness of the first coating may vary in a range of about 100 nm to about 2000 nm. In some embodiments, prior to PVD deposition, at least one thin seed or primer layer may be deposited on the plumbing fixture to achieve enhanced bonding characteristics with the subsequently PVD coating. For surfaces that are non-planar, the plumbing fixture may be set on a turntable that manually or automatically rotates as the first coating is applied. The second gas may include oxygen and acetylene.

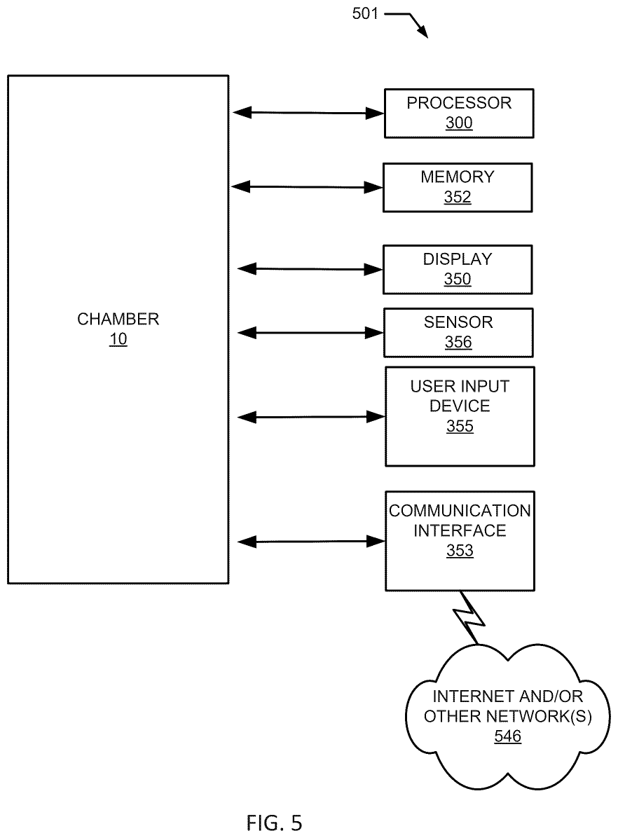

FIG. 5 illustrates an example controller 501 for operation of the chamber 10 and processes described herein. The controller 501 may include a processor 300, a memory 352, and a communication interface 353 for interfacing with devices or to the internet and/or other networks 346.

Optionally, the control system may include an input device 355 and/or a sensing circuit 356 in communication with any of the sensors (e.g., probes in the chamber 10.). The sensing circuit receives sensor measurements from one or more sensors. The input device may include any of the user inputs such as buttons, touchscreen, a keyboard, a microphone for voice inputs, a camera for gesture inputs, and/or another mechanism.

The processor 300 is configured to perform instructions 342 stored in memory 352 for executing the algorithms described herein. A display 350 may be an indicator or other screen output device. The display 350 may be combined with the user input device 355.

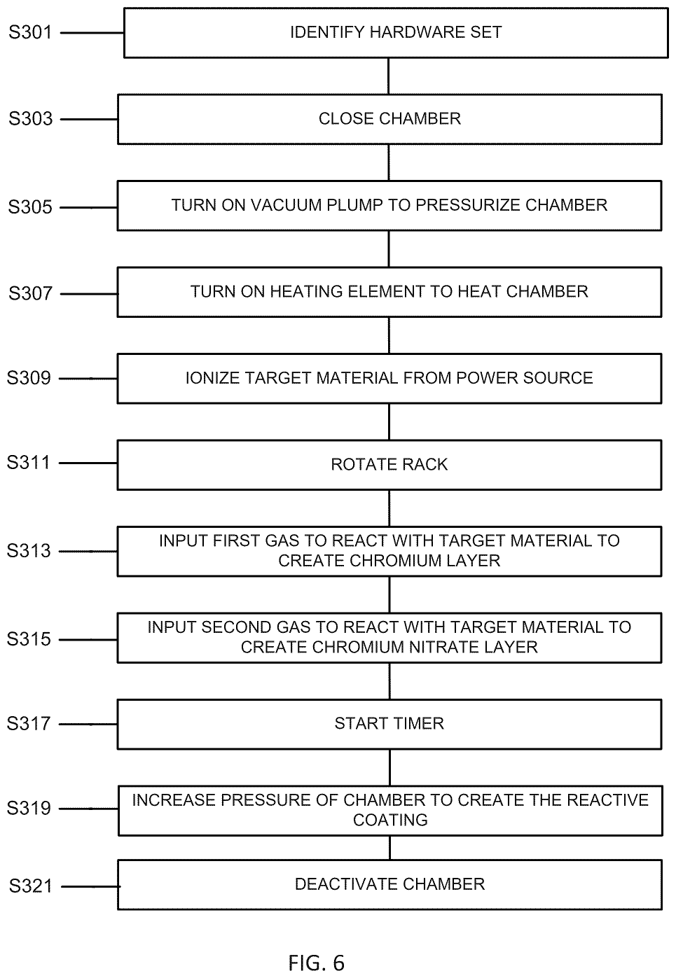

FIG. 6 illustrates a flow chart for the apparatus of FIG. 5. The acts of the flow chart may be performed by the controller 301. Additional, different of fewer acts may be included.

At act S301, the controller 301 (e.g., processor 300) receives an indication that hardware has been loaded into the chamber 10. The indication may be sensor data that detects the hardware. The indication may be an input from a user (e.g., turn on or press ready).

At act S303, the controller 301 (e.g., processor 300) provides an instruction to close the chamber 10. Closing the chamber may include lowering or otherwise moving a housing to enclose the chamber 10. Closing the chamber may include closing a window in the housing.

At act S305, the controller 301 (e.g., processor 300) provides an instruction to turn on a vacuum pump 40 to pressurize the chamber 10. The instruction may provide power to the vacuum pump 40 or open a valve connected between the vacuum pump 40 and the chamber 10.

At act S307, the controller 301 (e.g., processor 300) provides an instruction to turn on a heating element 60 to heat the chamber 10. The instruction may provide power to the heating element 60 and/or provide a target temperature to the heating element 60.

At act S309, the controller 301 (e.g., processor 300) provides an instruction to ionize the target material 30.

At act S311, the controller 301 (e.g., processor 300) provides an instruction to rotate the rack 20 in the chamber 10. The instruction may activate a motor connected to the rack 20. The instruction may provide a time for rotations, a speed, or a number of rotations.

At act S313, the controller 301 (e.g., processor 300) provides an instruction to input a first gas to the chamber 10 to react with the target material 30 to create the chromium layer.

At act S315, the controller 301 (e.g., processor 300) provides an instruction to create a second gas to react with the target material 30 to create a chromium nitrate layer.

At act S317, the controller 301 (e.g., processor 300) provides an instruction to start a timer. The timer may be set for a predetermined timer period. At act S317, the controller 301 (e.g., processor 300) provides an instruction to increase the pressure of the chamber 10 during creation of the reactive coating during the predetermined time period of the timer.

At act S321, the controller 301 (e.g., processor 300) provides an instruction to deactivate the chamber 10. Deactivation may include any combination of turning off the vacuum pump 40, turning off the power source 50, turning off the heating element 60, closing a valve in the gas inlet 70, stopping the rotation of the rack 20, and/or opening the chamber 10.

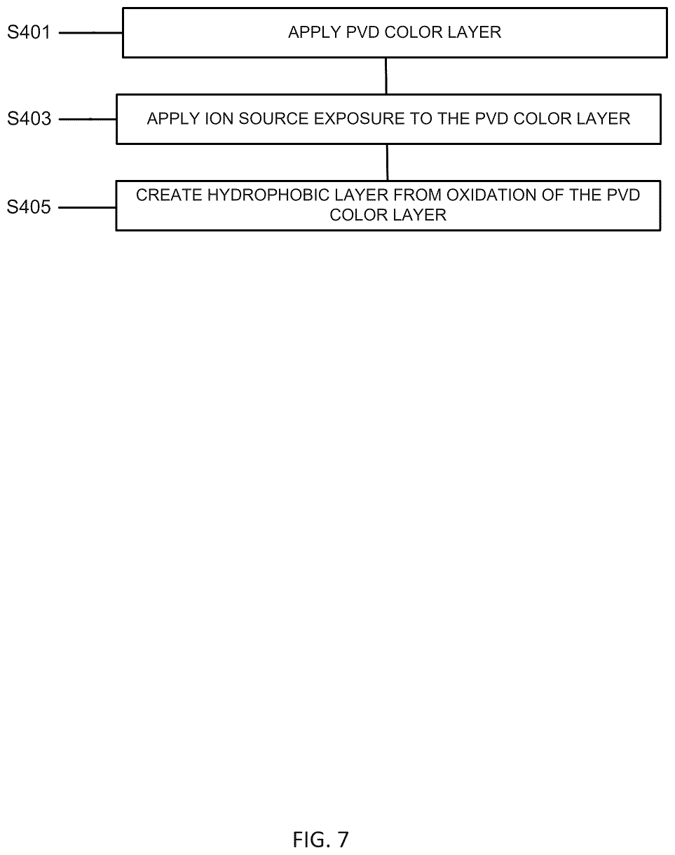

FIG. 7 illustrates a flow chart for formation of a cleanable surface on plumbing fixtures through modification of a coating of FIG. 1-4. The plumbing fixture may include a metal such as stainless steel. The plumbing fixture may be a faucet or other metal part in a water related appliance. Additional, different or fewer acts may be included.

At act S401, the PVD color layer is applied according to any of the embodiments described herein. The PVD color layer may be formed using heat and pressure in a chamber. In one example, at least one gas is provided to the chamber using multiple pressure levels over a time period. The pressure levels and/or time periods may be selected according to a desired.

At act S403, an ion source is applied to expose to the PVD color layer. The ion source may be within the chamber or otherwise connected to the chamber. The ion source may provide a plasma to the chamber. The ion source may be configured to oxidize one or more materials in a coating of the plumbing fixture. The ion source may oxidize the zirconium carbonite in the plumbing fixture.

In one example, a gas such as oxygen gas may be provided to the chamber.

The ion source may provide oxygen gas to the chamber. The ion source may cause at least a portion of the oxygen molecules in the oxygen gas to split to oxygen atoms. The oxygen becomes reactive and oxidize the zirconium carbonite in the plumbing fixture. The oxidized layer may operate as an adhesion layer to facilitate a coating for the hydrophobic layer. The oxidized layer may have a thickness in the range of 1-50 nanometers. One example may include a thickness in the range of 2-5 nanometers.

At act S405, a hydrophobic layer is created from the oxidation of the PVD color layer. For example, an organic material may be deposited on the adhesion layer through thermal evaporation PVD.

Processor 300 may be a general purpose or specific purpose processor, an application specific integrated circuit (ASIC), one or more programmable logic controllers (PLCs), one or more field programmable gate arrays (FPGAs), a group of processing components, or other suitable processing components. Processor 300 is configured to execute computer code or instructions stored in memory 352 or received from other computer readable media (e.g., embedded flash memory, local hard disk storage, local ROM, network storage, a remote server, etc.). The processor 300 may be a single device or combinations of devices, such as associated with a network, distributed processing, or cloud computing.

Memory 352 may include one or more devices (e.g., memory units, memory devices, storage devices, etc.) for storing data and/or computer code for completing and/or facilitating the various processes described in the present disclosure. Memory 352 may include random access memory (RAM), read-only memory (ROM), hard drive storage, temporary storage, non-volatile memory, flash memory, optical memory, or any other suitable memory for storing software objects and/or computer instructions. Memory 352 may include database components, object code components, script components, or any other type of information structure for supporting the various activities and information structures described in the present disclosure. Memory 352 may be communicably connected to processor 300 via a processing circuit and may include computer code for executing (e.g., by processor 300) one or more processes described herein. For example, memory 298 may include graphics, web pages, HTML files, XML files, script code, shower configuration files, or other resources for use in generating graphical user interfaces for display and/or for use in interpreting user interface inputs to make command, control, or communication decisions.

In addition to ingress ports and egress ports, the communication interface 353 may include any operable connection. An operable connection may be one in which signals, physical communications, and/or logical communications may be sent and/or received. An operable connection may include a physical interface, an electrical interface, and/or a data interface. The communication interface 353 may be connected to a network. The network may include wired networks (e.g., Ethernet), wireless networks, or combinations thereof. The wireless network may be a cellular telephone network, an 802.11, 802.16, 802.20, or WiMax network, a Bluetooth pairing of devices, or a Bluetooth mesh network. Further, the network may be a public network, such as the Internet, a private network, such as an intranet, or combinations thereof, and may utilize a variety of networking protocols now available or later developed including, but not limited to TCP/IP based networking protocols.

While the computer-readable medium (e.g., memory 352) is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

In a particular non-limiting, exemplary embodiment, the computer-readable medium can include a solid-state memory such as a memory card or other package that houses one or more non-volatile read-only memories. Further, the computer-readable medium can be a random access memory or other volatile re-writable memory. Additionally, the computer-readable medium can include a magneto-optical or optical medium, such as a disk or tapes or other storage device to capture carrier wave signals such as a signal communicated over a transmission medium. A digital file attachment to an e-mail or other self-contained information archive or set of archives may be considered a distribution medium that is a tangible storage medium. Accordingly, the disclosure is considered to include any one or more of a computer-readable medium or a distribution medium and other equivalents and successor media, in which data or instructions may be stored. The computer-readable medium may be non-transitory, which includes all tangible computer-readable media.

In an alternative embodiment, dedicated hardware implementations, such as application specific integrated circuits, programmable logic arrays and other hardware devices, can be constructed to implement one or more of the methods described herein. Applications that may include the apparatus and systems of various embodiments can broadly include a variety of electronic and computer systems. One or more embodiments described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

The illustrations of the embodiments described herein are intended to provide a general understanding of the structure of the various embodiments. The illustrations are not intended to serve as a complete description of all of the elements and features of apparatus and systems that utilize the structures or methods described herein.

Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

While this specification contains many specifics, these should not be construed as limitations on the scope of the invention or of what may be claimed, but rather as descriptions of features specific to particular embodiments of the invention. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

It is intended that the foregoing detailed description be regarded as illustrative rather than limiting and that it is understood that the following claims including all equivalents are intended to define the scope of the invention. The claims should not be read as limited to the described order or elements unless stated to that effect. Therefore, all embodiments that come within the scope and spirit of the following claims and equivalents thereto are claimed as the invention.

1. A method for application of a finish for a hardware set, the method comprising:
heating a chamber;
pressurizing the chamber including the hardware set to create a vacuum in the chamber;
applying at least one gas to an ionized target material in the chamber for a non-reactive coating layer; and
providing at least one gas to the chamber at a dynamically increasing pressure over a predetermined time range for a coating having a predetermined color.

2. The method of claim 1, further comprising:
applying an ion source to the coating having the predetermined color; and
forming a hydrophobic layer to the hardware set through oxidation.

3. The method of claim 1, wherein the at least one gas reacts with the ionized target material to create the non-reactive coating layer.

4. The method of claim 1, wherein the at least one gas is applied to the ionized target material a predetermined number of times.

5. The method of claim 1, wherein the predetermined color is black or graphite.

6. The method of claim 1, wherein the predetermined time range is greater than 10 minutes.

7. The method of claim 1, wherein the non-reactive coating layer comprises a first layer made of chromium and a second layer made of chromium nitride.

8. The method of claim 7, wherein the first layer is applied for a first time period followed by the second layer for a second time period.

9. The method of claim 1, wherein the ionized target material is titanium, chromium, or zirconium.

10. The method of claim 1, wherein the at least one gas is nitrogen, oxygen, or acetylene.

11. The method of claim 1, wherein the pressure and the heat of the chamber is reduced to a first level.

12. The method of claim 11, wherein the pressure is further reduced to a second level.

13. An apparatus for applying a finish to a hardware set, the apparatus comprising:
a rack configured to hold the hardware set in a chamber and to distribute the finish on the hardware set;
a vacuum pump to create a vacuum in the apparatus;
an electric input to increase a voltage of a target material;
a heating element to increase a temperature in the apparatus; and
at least one gas inlet pipe configured to gas for a nonreactive coating to the hardware set and gas for a reactive coating.

14. The apparatus of claim 13, wherein the at least one gas inlet pipe includes a plurality of pipes.

15. The apparatus of claim 13, wherein the rack rotates around the target material.

16. The apparatus of claim 13, wherein the electric input increases the voltage of the target material to ionize the target material.

17. The apparatus of claim 16, wherein the gas reacts with the ionized target material to form the nonreactive coating.

18. The apparatus of claim 13, wherein the vacuum pump reduces pressure in the chamber to a first level.

19. The apparatus of claim 18, wherein the vacuum pump further reduces the pressure in the chamber to a second level.

20. A finish comprising
a base substrate;
a chromium layer formed from a first gas reacting with an ionized target material; and
a chromium nitrate layer formed from a second gas reacting with the ionized target material.

21-26. (canceled)
